(19) United States
(12) Patent Application Publication
(10) Pub. No.: US 2026/0206402 A1
(43) Pub. Date: Jul. 16, 2026

(54) PATTERNED SAPPHIRE SUBSTRATE WITH INTEGRATED PHOTONIC LAYER

(71) Applicant: Lumileds LLC, San Jose, CA (US)

(72) Inventor: Antonio Lopez Julia, Eindhoven (NL)

(21) Appl. No.: 19/138,162

(22) PCT Filed: Dec. 11, 2023
(86) PCT No.: PCT/US2023/083359

§ 371 Date: Jun. 12, 2025

Related U.S. Application Data
(60) Provisional application No. 63/432,957, filed on Dec. 15, 2022.

(51) Int. Cl. H10H 29/80; H10H 20/825

(52) U.S. Cl. CPC H10H 29/872; H10H 20/825

(57) ABSTRACT

Discussed herein are devices, systems, and methods for sapphire substrate lighting devices with improved luminance. A segmented lighting apparatus includes a sapphire substrate, a patterned low refractive index material on the sapphire substrate, a photonic layer on the patterned low refractive index material, and a light-generating material on the photonic layer.

This application claims the benefit of priority to U.S. Provisional Patent Application Ser. No. 63/432,957, filed Dec. 15, 2022, which is incorporated herein by reference in its entirety.

### TECHNICAL FIELD

The present disclosure relates to a light-emitting apparatus, a light-emitting apparatus system, and methods of making and using a light-emitting apparatus. The light-emitting apparatus is configured to maximize light outcoupling and package efficiency in a light-emitting diode (LED) die.

### BACKGROUND

Patterned sapphire substrates (PSS) enable flip-chip (FC) die architectures where light may efficiently escape from the substrate layer by means of surface corrugation at a gallium nitride (GaN)-sapphire interface. In contrast to thin-film-flip-chip (TFFC) architectures, PSS based light emitting diodes (LEDs) can benefit from a high refractive index of the PSS. The refractive index of the PSS is closer to the refractive index of the GaN than any other practical encapsulation material.

### BRIEF DESCRIPTION OF THE DRAWINGS

The figures show various views of an apparatus, system, or method, including a control system that can alter light emerging from one or more light emitting diodes (LEDs), in accordance with some embodiments. The terms “front,” “rear,” “top,” “side,” and other directional terms are used merely for convenience in describing the apparatuses and systems and other elements and should not be construed as limiting in any way.

FIG. 1 illustrates, by way of example, a diagram of an embodiment of a patterned sapphire substrate.

FIG. 2 illustrates, by way of example, a diagram of an embodiment of a sapphire-based flip-chip (FC) LED device.

FIG. 3 illustrates, by way of example, a diagram of a graph of back reflected loss and non-extracted loss for a variety of PSS die layers.

FIG. 4 illustrates, by way of example, a cross-section diagram of a PSS structure (PSS3).

FIGS. 5 and 6 illustrate, by way of example, respective graphs of transmittance and reflectance, respectively, versus angle of incidence (AOI) in a GaN-sapphire device with 550 nm light.

FIG. 7 illustrates, by way of example, a diagram of an embodiment an improved PSS3 lighting device.

FIG. 8 illustrates, by way of example, a graph of transmittance versus scatter angle, for a variety of sapphire substrate-based LED devices.

FIG. 9 illustrates, by way of example, a diagram of an embodiment of a segmented light apparatus control system.

FIG. 10 illustrates, by way of example, a diagram of an embodiment of an array of segmented LEDs.

FIG. 11 illustrates, by way of example, a diagram of an embodiment of a method for making a segmented LED device with improved transmittance.

FIG. 12 illustrates in more detail an embodiment of a chip-level implementation of a system supporting lighting apparatus functionality.

FIG. 13 illustrates, by way of example, a logical block diagram of a system that includes circuitry that can be included in a lighting apparatus package.

### DETAILED DESCRIPTION

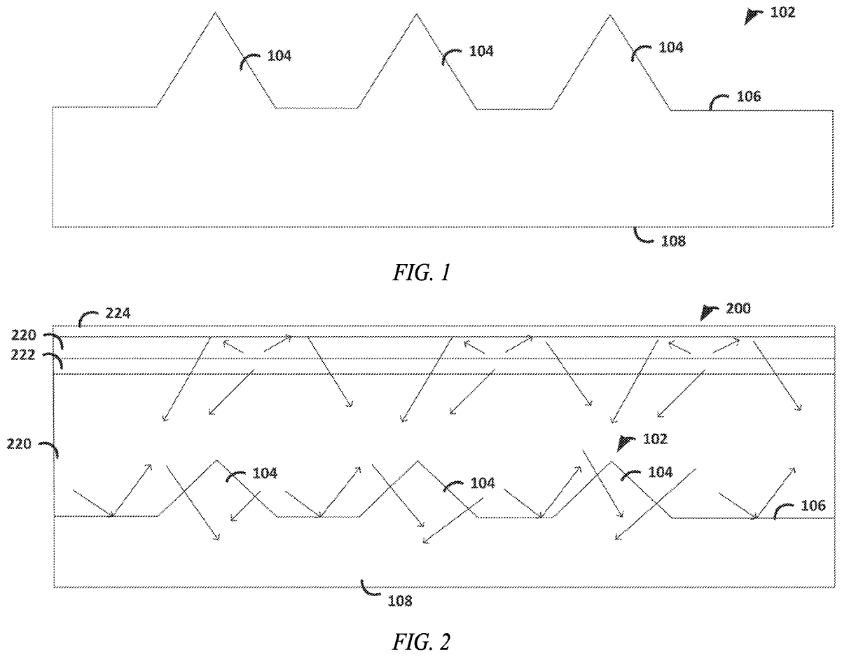

FIG. 1 illustrates, by way of example, a diagram of an embodiment of a patterned sapphire substrate 102. A bottom surface 106 of the sapphire substrate 102 is corrugated to include features 104. The features 104 can be folds, wrinkles, ridges, protrusions, or the like. The features 104 allow a GaN or other light-generating material to be adhered to the bottom surface 106. Light escapes the sapphire substrate 102 through a top surface 108. The top surface 108 is generally planar (within a one or two microns of being planar).

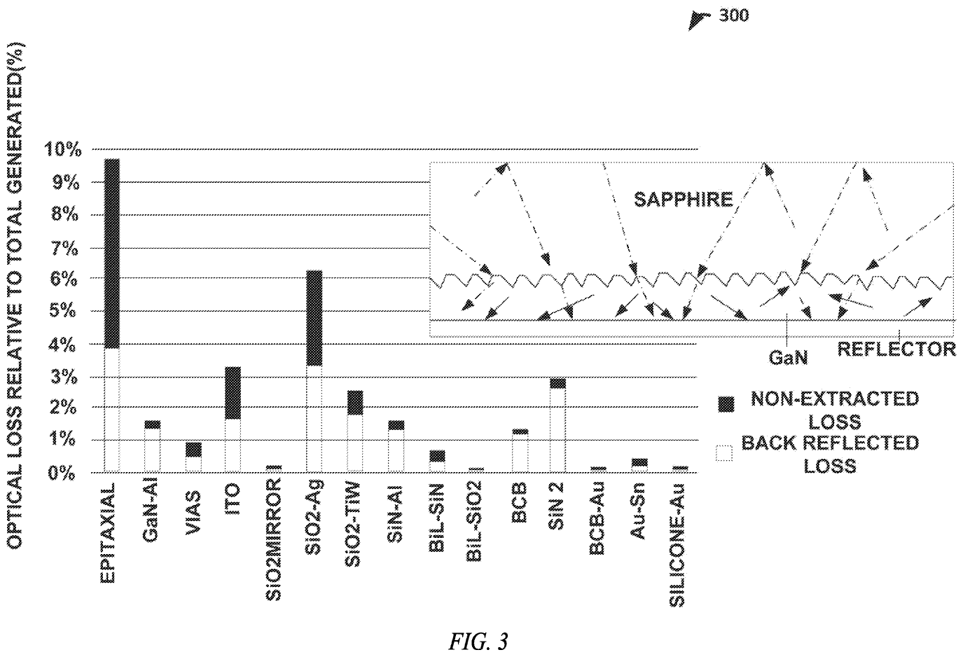

FIG. 2 illustrates, by way of example, a diagram of an embodiment of a sapphire-based flip-chip (FC) LED device 200. The PSS 102 (PSS) enables the FC die architecture of FIG. 2. Using the FC die architecture, light may efficiently escape from the top surface 108 of the PSS 102 by means of surface corrugation, in the form of features 104, at the interface of the GaN 220 and the sapphire substrate 102. In contrast to thin-film-FC (TFFC) architectures, PSS based LEDs can benefit from a high refractive index (a refractive index greater than 1.5, while a low refractive index is any refractive index less than, or equal to 1.5) of the PSS 102, which is closer to the refractive index of the GaN 220 than any other practical encapsulation material. This, however, can have negative implications in pcLED with regards to package efficiency as the transmission of light reflected at a phosphor layer (on the top surface 108 of the PSS 102) back into the absorbing epitaxial/die layers will be higher. FIG. 3 illustrates a graph of back reflected loss and non-extracted loss at various layers of a PSS LED.

The GaN 220 can include a quantum well 222 through which light is generated. A reflector 224 can be situated to reflect light towards the PSS 102.

FIG. 3 illustrates, by way of example, a diagram of a graph 300 of back reflected loss and non-extracted loss for a variety of PSS die layers. As can be seen, the biggest losses for both back reflected losses and non-extracted losses are from an epitaxial layer.

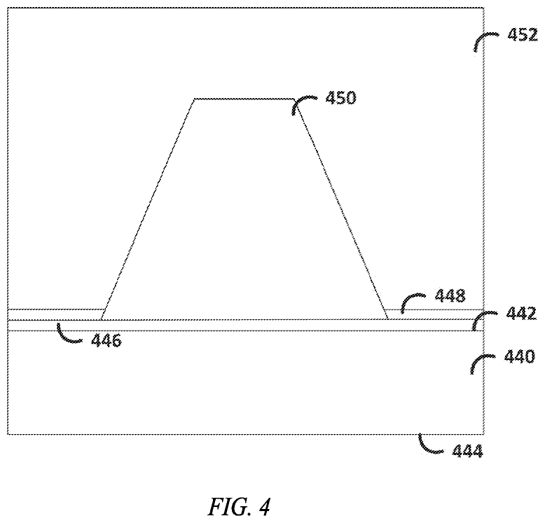

FIG. 4 illustrates, by way of example, a cross-section diagram of a PSS structure (PSS3) 400. The PSS3 structure 400 includes a planar sapphire substrate 440 instead of a PSS as in FIGS. 1 and 2. The PSS3 structure 400 also includes a material 450 with a low refractive index. The material 450 can include silicon dioxide (SiO2), or the like. In the structure 400, the features 104 of the PSS 102 are replaced with the patterned material 450. The sapphire substrate 440 includes a generally planar bottom surface 442 and an opposing generally planar top surface 444. The top surface 444 is the surface through which the PSS3 structure 400 emits light. An aluminum nitride (AlN) material 446 is situated on (e.g., in contact with) the bottom surface 442 of the sapphire substrate 440. A nucleation material 448 is situated on the side of the patterned material 450 The patterned material 450 is situated on the AlN material 446. A GaN 452 is grown on the nucleation layer 448 and the patterned material 450.

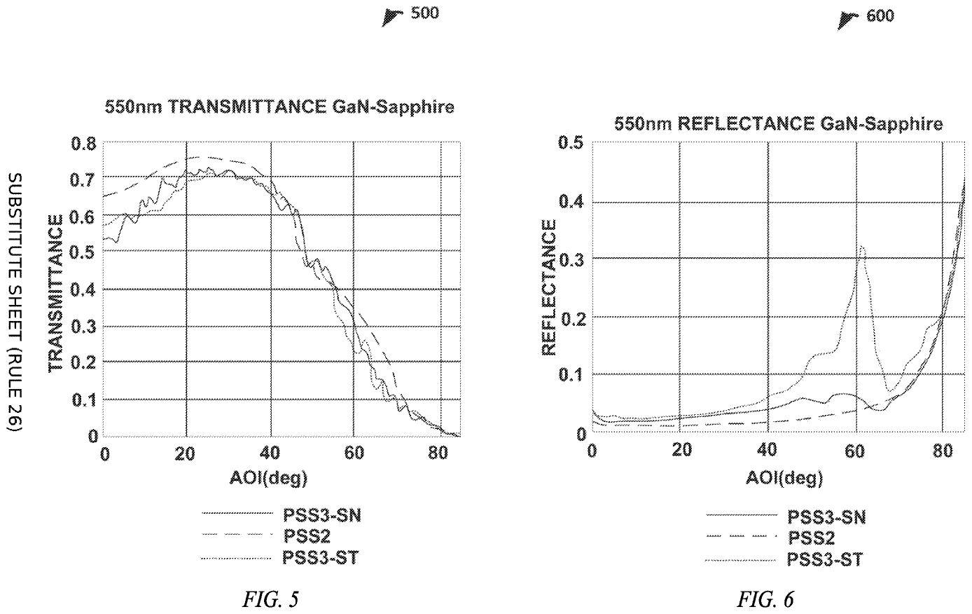

FIGS. 5 and 6 illustrate, by way of example, respective graphs 500, 600 of transmittance and reflectance, respectively, versus angle of incidence (AOI) in a GaN-sapphire device with 550 nm light. As can be seen, the benefits of PSS3 in terms of reflection characteristics as seen by the radiation from the phosphor side of the emitter. FIGS. 5 and 6 also highlight drawback of the PSS3 technology, i.e. the transmission power from GaN into sapphire drops with respect to a PSS2 reference. Embodiments include a modification of the PSS3 structure 400 to mitigate this problem by means of integrating one or more photonic layers.

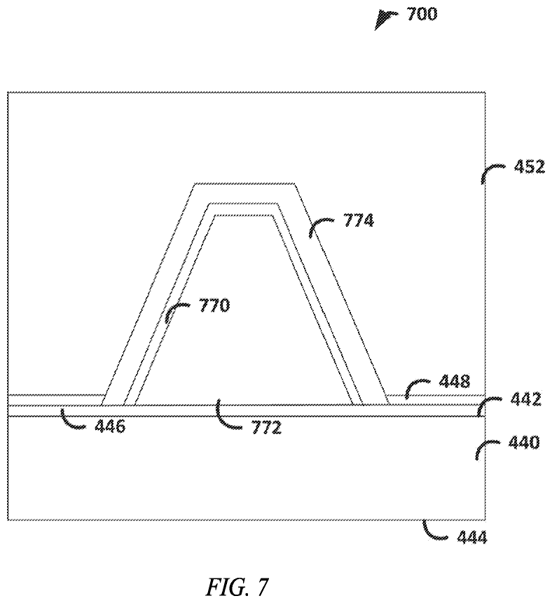

FIG. 7 illustrates, by way of example, a diagram of an embodiment an improved PSS3 lighting device 700. The device 700 is similar to the device 400 with the device 700 including a photonic layer stack on the patterned material 772. The photonic layer stack includes a photonic material 770 and another material 774. The material 774 can include a low index of refraction. The photonic material 770 can be on the patterned material 772. The material 774 can be the same material as the patterned material 772. The material 774 can be on the photonic material 770.

As in the device 400 of FIG. 4, the material 450 can include silicon dioxide (SiO2), or the like. In the structure 700, the features 104 of the PSS 102 are replaced with the patterned material 772 and the photonic layer 770. The sapphire substrate 440 includes a generally planar bottom surface 442 and an opposing generally planar top surface 444. The top surface 444 is the surface through which the PSS3 structure 700 emits light. An aluminum nitride (AlN) material 446 is situated on (e.g., in contact with) the bottom surface 442 of the sapphire substrate 440. A nucleation material 448 is situated on the side of the patterned material 772. The patterned material 772 is situated on the AlN material 446. GaN 452 is grown on the nucleation layer 448 and the patterned material 772 that is not covered by the photonic material 770.

The photonic material 770 can conform to the shape of the patterned material 772 that is situated in contact with the AlN 446, not in direct contact with the nucleation layer 448, or a combination thereof. The photonic material 770 can include niobium pentoxide (Nb2O5), titanium dioxide (TiO2), or the like.

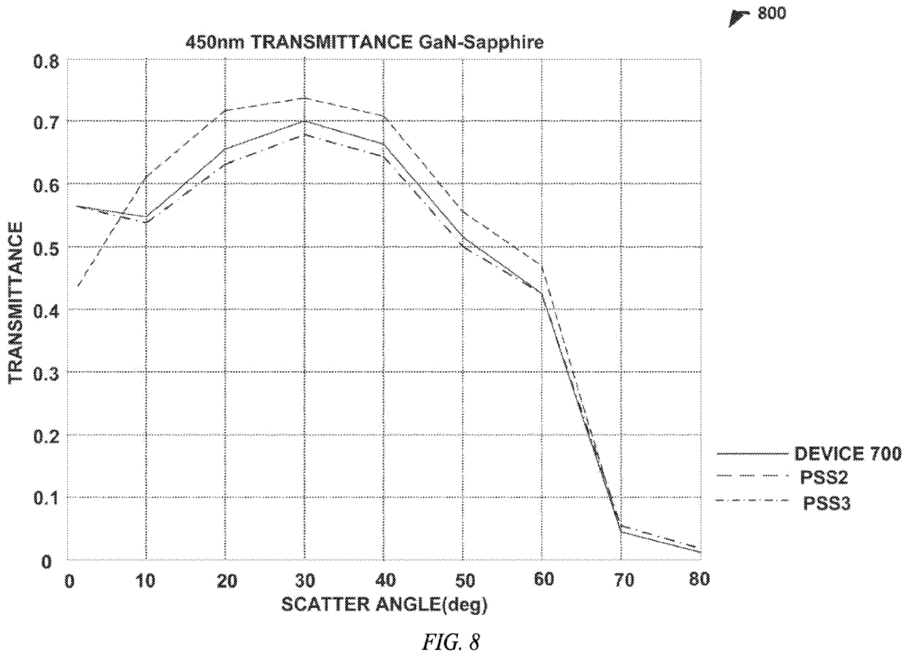

This photonic layer stack has the function of an anti-reflective coating (AR coating) or dichroic filter. The photonic layer stack increase transmission of pump radiation from the GaN 452 to the sapphire substrate 440 (typically at or near 440 nm). The photonic layer stack can reflect long wavelength radiation (e.g., that of emission from a phosphor layer). The photonic layer stack can act as a filter. The photonic layer stack can be composed of high and low refractive index layer materials such as SiO2 and TiO2 or Nb2O5. FIG. 7 depicts the case of a single stack of two materials, which is enough to significantly improve the transmission of reference PSS3 as shown in FIG. 8. Standard fabrication techniques can be deployed to realize the photonic layer stack.

FIG. 8 illustrates, by way of example, a graph 800 of transmittance versus scatter angle, for a variety of sapphire substrate-based LED devices. As can be seen in FIG. 8, the device 700 transmittance is an improvement over the PSS3 architecture 400 from FIG. 4.

The device 700 can be a part of a segmented LED. Segmented LEDs containing multiple addressable junction segments find application in various dynamic lighting and display systems.

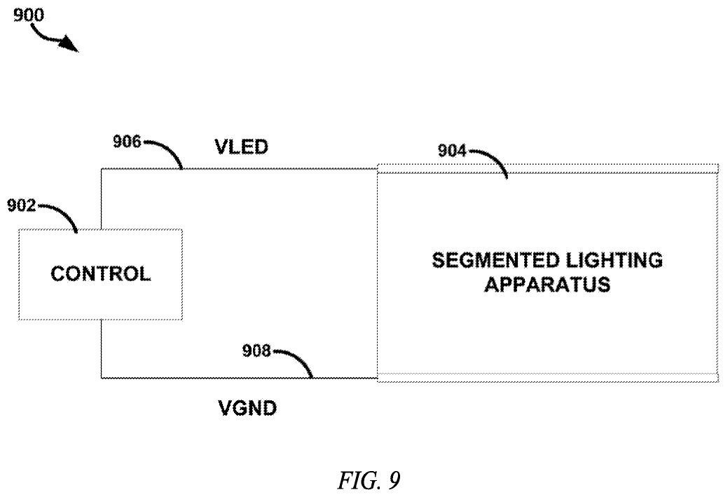

FIG. 9 illustrates, by way of example, a diagram of an embodiment of a segmented light apparatus control system 900. The system 900 as illustrated includes control circuitry 902 that provides power distributed by a plurality of LED drivers to lighting apparatus 904 that includes a matrix of segmented LEDs, such as the lighting apparatus 700. The control circuitry 902 provides a constant direct current (DC) voltage V_{LED} 906 and a constant reference voltage V_{GND} 908. The control circuitry 902 can fix the voltage supply to the DC level of V_{LED} 906.

The control circuitry 902 can include electrical or electronic components configured to implement power provision to the LED(s) of the segmented LEDs of the segmented lighting apparatus 904 (sometimes called the uLED die). The electric or electronic components can include one or more transistors, resistors, capacitors, diodes, inductors, oscillators, switches, logic gates, multiplexers, analog to digital converters, digital to analog converters, amplifiers, rectifiers, modulators, demodulators, processors, memory devices, or the like.

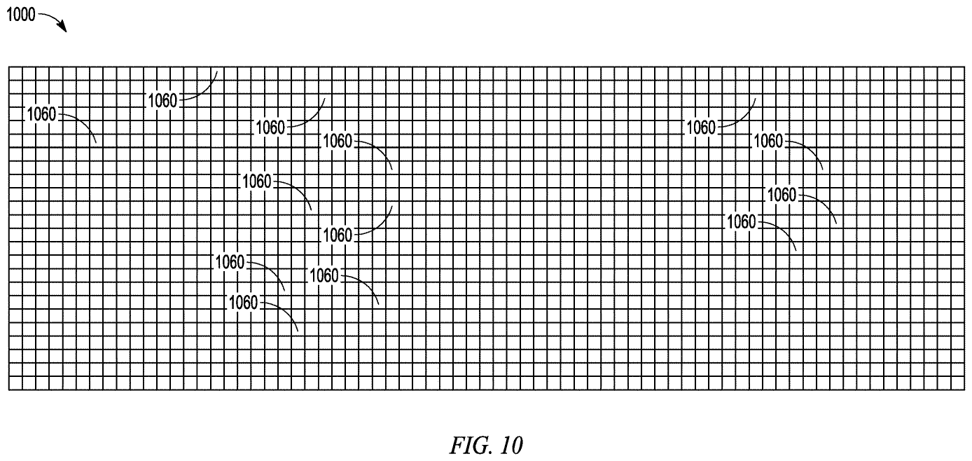

FIG. 10 illustrates, by way of example, a diagram of an embodiment of an array of segmented LEDs 1000. The segmented LED 904 can include the array of segmented LEDs 1000 implemented using the device 700.

Each of the LEDs 1060 is individually addressable and controllable.

Each of the LEDs 1060 forms its own “segment” and is physically separate in an active silicon layer (sometimes called a “quantum well”) so as to have its own active light emitting region. The LEDs 1060 are thus said to be segmented. Each of the LEDs can emit into the sapphire substrate 102.

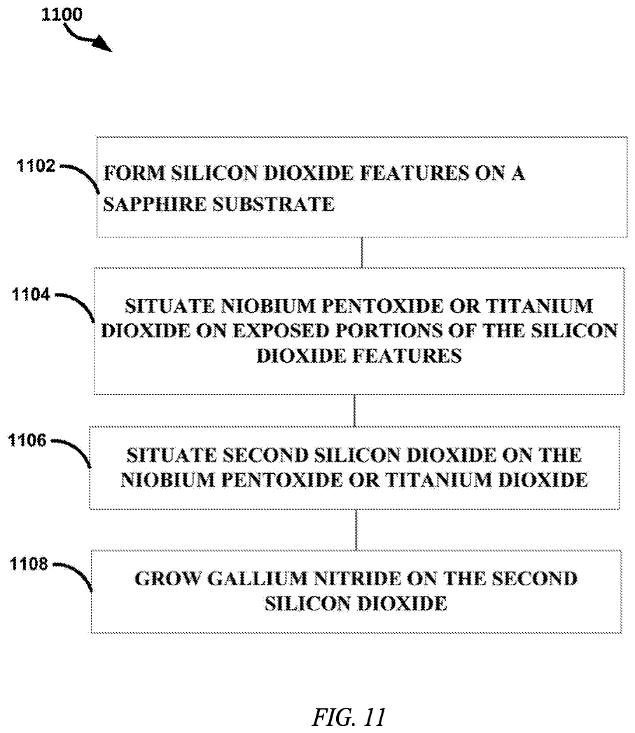

FIG. 11 illustrates, by way of example, a diagram of an embodiment of a method 1100 for making a segmented LED device with improved transmittance. The method 1100 can be performed, at least in part, to create the device 700, other component, or a combination thereof. The method 1100, as illustrated, includes forming silicon dioxide features on a sapphire substrate, at operation 1102; situating niobium pentoxide or titanium dioxide on exposed portions of the silicon dioxide features, at operation 1104; situating second silicon dioxide on the niobium pentoxide or titanium dioxide, at operation 1106; and growing gallium nitride on the second silicon dioxide, at operation 1108.

The method 1100 can further include situating an aluminum nitride in contact with a bottom surface of the silicon substrate. The bottom surface can be situated to receive light from the gallium nitride and opposite a top surface of the sapphire substrate through which light is emitted. The aluminum nitride can be situated between the bottom surface and the gallium and between the sapphire substrate and the silicon dioxide features. The method 1100 can further include situating a nucleation layer on the sapphire substrate so the nucleation layer horizontally separates features of the silicon dioxide features and is vertically between the sapphire substrate and the gallium nitride. The method 1100 can further include, wherein the sapphire substrate includes a top surface through which the light is emitted and an opposing bottom surface through which light from the gallium nitride is received. The method 1100 can further include, wherein the niobium pentoxide or titanium dioxide conforms to surfaces of the silicon dioxide features, the surfaces facing away from the top surface.

What follows are some details regarding the segmented LEDs 904 that can be made using the device 700 and some application and control considerations followed by some examples.

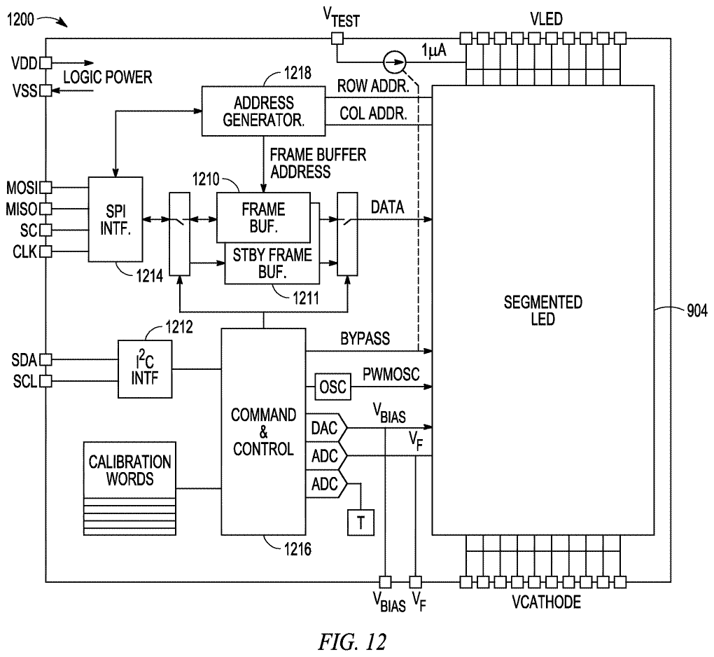

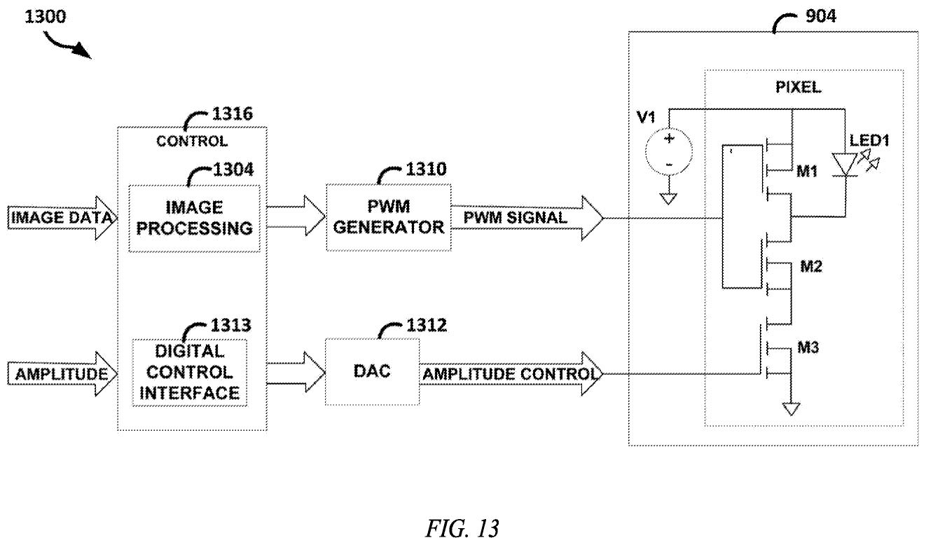

FIG. 12 illustrates in more detail an embodiment of a chip-level implementation of a system 1200 supporting functionality, such as discussed with respect to, for example, FIGS. 7-11. The electric or electronic components coupled to the segmented LED 904 in FIG. 12 or 13 can be electrically coupled to the segmented LED 904 through a submount, mounting pads, a combination thereof, or the like. The system 1200 includes a command and control module 1216 (sometimes called control circuitry, which may be similar to or the same as the control circuitry of FIG. 9) able to implement pixel or group pixel level control of amplitude and duty cycle for circuitry and procedures such as discussed with respect to FIGS. 7-11 and elsewhere herein. In some embodiments, the system 1200 further includes a frame buffer 1210 for holding generated or processed images that can be supplied to the segmented LED 904. Other modules can include digital control interfaces, such as a serial bus (e.g., an Inter-Integrated Circuit (I²C) serial bus) or Serial Peripheral Interface (SPI) 1214, that are configured to transmit control data or instructions or response data.

In operation, system 1200 can accept image or other data from a vehicle or other source that arrives via the SPI 1214. Successive images or video data can be stored in an image frame buffer 1210. If no image data is available, one or more standby images held in a standby image buffer 1211 can be directed to the image frame buffer 1210. Such standby images can include, for example, an intensity and spatial pattern consistent with legally allowed low beam headlamp radiation patterns of a vehicle, or default light radiation patterns for architectural lighting or displays.

In operation, pixels in the images are used to define response of corresponding LED pixels in the active, with intensity and spatial modulation of LED pixels being based on the image(s). To reduce data rate issues, groups of pixels (e.g., 5×5 blocks), rather than individual pixels, can be controlled as single blocks in some embodiments. In some embodiments, high speed and high data rate operation is supported, with pixel values from successive images able to be loaded as successive frames in an image sequence at a rate between 30 Hz and 100 Hz, with 60 Hz being typical. PWM can be used to control each pixel to emit light in a pattern and with an intensity at least partially dependent on the image held in the image frame buffer 1210.

In some embodiments, the system 1200 can receive logic power via V_{dd} and Vₛₛ pins. An active matrix receives power for LED array control by multiple VLED and V_{Cathode} pins. The SPI 1214 can provide full duplex mode communication using a master-slave architecture with a single master. The master device originates the frame for reading and writing. Multiple slave devices are supported through selection with individual slave select (SS) lines. Input pins can include a Master Output Slave Input (MOSI), a Master Input Slave Output (MISO), a chip select (SC), and clock (CLK), all connected to the SPI 1214. The SPI 1214 connects to an address generator, frame buffer, and a standby frame buffer. Pixels can have parameters set and signals or power modified (e.g. by power gating before input to the frame buffer, or after output from the frame buffer via pulse width modulation or power gating) by a command and control module. The SPI 1214 can be connected to an address generation module 1218 that in turn provides row and address information to the active matrix 1220. The address generation module 1218 in turn can provide the frame buffer address to the frame buffer 1210.

In some embodiments, the command and control module 1216 can be externally controlled via the serial bus 1212. A clock (SCL) pin and data (SDA) pin, such as with 7-bit addressing can be supported. The command and control module 1216 can include a digital to analog converter (DAC) and two analog to digital converters (ADC). The DAC and ADCs are respectively used to set V_{bias} for a connected active matrix, help determine maximum V_{f}, and determine system temperature. Also connected are an oscillator (OSC) to set the pulse width modulation oscillation (PWMOSC) frequency for the active matrix 1220. In one embodiment, a bypass line is also present to allow address of individual pixels or pixel blocks in the active matrix for diagnostic, calibration, or testing purposes. The active matrix 1220 can be further supported by row and column select that is used to address individual pixels, which are supplied with a data line, a bypass line, a PWMOSC line, a V_{bias} line, and a V_{f} line.

As will be understood by a person of ordinary skill in the art, in some embodiments the described circuitry and the segmented LED can be packaged and optionally include the submount or printed circuit board connected for powering and controlling light production by the semiconductor LED. In certain embodiments, the printed circuit board can also include electrical vias, heat sinks, ground planes, electrical traces, and flip chip or other mounting systems. The submount or printed circuit board may be formed of any suitable material, such as ceramic, silicon, aluminum, etc. If the submount material is conductive, an insulating layer is formed over the substrate material, and the metal electrode pattern is formed over the insulating layer. The submount can act as a mechanical support, providing an electrical interface between electrodes on the LED and a power supply, and also provide heat sinking.

In some embodiments, the active matrix 1220 can be formed from light emitting elements of various types, sizes, and layouts. In one embodiment, one or two dimensional matrix arrays of individually addressable light emitting diodes (LEDs) can be used. Commonly N×M arrays where N and M are respectively between two and one thousand can be used. Individual LED structures can have a square, rectangular, hexagonal, polygonal, circular, arcuate or other surface shape. Arrays of the LED assemblies or structures can be arranged in geometrically straight rows and columns, staggered rows or columns, curving lines, or semi-random or random layouts. LED assemblies can include multiple LEDs formed as individually addressable pixel arrays are also supported. In some embodiments, radial or other non-rectangular grid arrangements of conductive lines to the LED can be used. In other embodiments, curving, winding, serpentine, and/or other suitable non-linear arrangements of electrically conductive lines to the LEDs can be used.

In some embodiments, arrays of microLEDs (μLEDs or uLEDs) can be used. uLEDs can support high density pixels having a lateral dimension less than 100 μm by 100 μm. In some embodiments, uLEDs with dimensions of about 50 μm in diameter or width and smaller can be used. Such uLEDS can be used for the manufacture of color displays by aligning, in close proximity, uLEDs comprising red, blue, and green wavelengths. In other embodiments, uLEDS can be defined on a monolithic gallium nitride (GaN) or other semiconductor substrate, formed on segmented, partially, or fully divided semiconductor substrate, or individually formed or panel assembled as groupings of segmented LEDs. In some embodiments, the segmented LED 904 can include small numbers of uLEDs positioned on substrates that are centimeter scale area or greater. In some embodiments, the segmented LED 904 can support uLED pixel arrays with hundreds, thousands, or millions of LEDs positioned together on centimeter scale area substrates or smaller. In some embodiments, uLEDS can include LEDs sized between 30 microns and 500 microns. In some embodiments, each of the light emitting pixels in the light emitting pixel array can be positioned at least 1 millimeter apart to form a sparse LED array. In other embodiments sparse LED arrays of light emitting pixels can be positioned less than 1 millimeter apart and can be spaced apart by distances ranging from 30 microns to 500 microns. The LEDs can be embedded in a solid or a flexible substrate, which can be at least in part transparent. For example, the light emitting pixel arrays can be at least partially embedded in glass, ceramic, or polymeric materials.

Light emitting matrix pixel arrays, such as discussed herein, may support applications that benefit from fine-grained intensity, spatial, and temporal control of light distribution. This may include, but is not limited to, precise spatial patterning of emitted light from pixel blocks or individual pixels. Depending on the application, emitted light may be spectrally distinct, adaptive over time, and/or environmentally responsive. The light emitting pixel arrays may provide pre-programmed light distribution in various intensity, spatial, or temporal patterns. The emitted light may be based at least in part on received sensor data and may be used for optical wireless communications. Associated optics may be distinct at a pixel, pixel block, or device level. An example light emitting pixel array may include a device having a commonly controlled central block of high intensity pixels with an associated common optic, whereas edge pixels may have individual optics. Common applications supported by light emitting pixel arrays include video lighting, automotive headlights, architectural and area illumination, street lighting, and informational displays.

Light emitting matrix pixel arrays may be used to selectively and adaptively illuminate buildings or areas for improved visual display or to reduce lighting costs. In addition, light emitting pixel arrays may be used to project media facades for decorative motion or video effects. In conjunction with tracking sensors and/or cameras, selective illumination of areas around pedestrians may be possible. Spectrally distinct pixels may be used to adjust the color temperature of lighting, as well as support wavelength specific horticultural illumination.

Street lighting is an application that may benefit from use of light emitting pixel arrays. A single light emitting array may be used to mimic various street light types, allowing, for example, switching between a Type I linear streetlight and a Type IV semicircular streetlight by appropriate activation or deactivation of selected pixels. In addition, street lighting costs may be lowered by adjusting light beam intensity or distribution according to environmental conditions or time of use. For example, light intensity and area of distribution may be reduced when pedestrians are not present. If pixels of the light emitting pixel array are spectrally distinct, the color temperature of the light may be adjusted according to respective daylight, twilight, or night conditions.

Light emitting arrays are also suited for supporting applications requiring direct or projected displays. For example, warning, emergency, or informational signs may all be displayed or projected using light emitting arrays. This allows, for example, color changing or flashing exit signs to be projected. If a light emitting array is composed of a large number of pixels, textual or numerical information may be presented. Directional arrows or similar indicators may also be provided.

Vehicle headlamps are a light emitting array application that requires large pixel numbers and a high data refresh rate. Automotive headlights that actively illuminate only selected sections of a roadway can used to reduce problems associated with glare or dazzling of oncoming drivers. Using infrared cameras as sensors, light emitting pixel arrays activate only those pixels needed to illuminate the roadway, while deactivating pixels that may dazzle pedestrians or drivers of oncoming vehicles. In addition, off-road pedestrians, animals, or signs may be selectively illuminated to improve driver environmental awareness. If pixels of the light emitting pixel array are spectrally distinct, the color temperature of the light may be adjusted according to respective daylight, twilight, or night conditions. Some pixels may be used for optical wireless vehicle to vehicle communication.

An LED light module can include matrix LEDS, alone or in conjunction with primary or secondary optics, including lenses or reflectors. To reduce overall data management requirements, the light module can be limited to on/off functionality or switching between relatively few light intensity levels. Full pixel level control of light intensity is not necessarily supported.

In operation, pixels in the images are used to define response of corresponding LED pixels in the pixel module, with intensity and spatial modulation of LED pixels being based on the image(s). To reduce data rate issues, groups of pixels (e.g. 5×5 blocks) can be controlled as single blocks in some embodiments. High speed and high data rate operation is supported, with pixel values from successive images able to be loaded as successive frames in an image sequence at a rate between 30 Hz and 100 Hz, with 60 Hz being typical. In conjunction with a pulse width modulation module, each pixel in the pixel module can be operated to emit light in a pattern and with intensity at least partially dependent on the image held in the image frame buffer.

In the foregoing described embodiments, intensity of a uLED can be separately controlled and adjusted by setting appropriate ramp times and pulse width for each LED pixel using a suitable lighting logic, control module, and/or PWM module.

FIG. 13 illustrates, by way of example, a logical block diagram of a system 1300 that includes circuitry that can be included in a lighting apparatus package. Processing modules that facilitate efficient usage of the system 1300 are illustrated in FIG. 13. The system 1300 includes a control module 1316 (sometimes called control circuitry, such as the control circuitry 902) able to implement pixel or group pixel level control of amplitude and duty cycle for circuitry and procedures such as discussed with respect to FIGS. 7-11. In some embodiments, the system 1300 further includes an image processing module 1304 to generate, process, or transmit an image, and digital control interfaces 1313, such as inter-integrated circuit (I2C), serial peripheral interface (SPI), controller area network (CAN), universal asynchronous receiver transmitter (UART), or the like, that is configured to transmit control data and/or instructions. The digital control interfaces 1313 and control module 1316 may include a system microcontroller and any type of wired or wireless module configured to receive a control input from an external device. By way of example, a wireless module may include Bluetooth, Zigbee, Z-wave, mesh, WiFi, near field communication (NFC) and/or peer to peer modules may be used. The microcontroller may be any type of special purpose computer or processor that may be embedded in an LED lighting system and configured or configurable to receive inputs from the wired or wireless module or other modules in the LED system and provide control signals to other modules based thereon. Algorithms implemented by the microcontroller or other suitable control module 1316 may be implemented in a computer program, software, or firmware incorporated in a non-transitory computer-readable storage medium for execution by the special purpose processor. Examples of non-transitory computer-readable storage mediums include a read only memory (ROM), a random access memory (RAM), a register, cache memory, and semiconductor memory devices. The memory may be included as part of the microcontroller or may be implemented elsewhere, either on or off a printed circuit or electronics board

The term module, as used herein, may refer to electrical and/or electronic components disposed on individual circuit boards that may be soldered to one or more electronics boards. The term module may, however, also refer to electrical and/or electronic components that provide similar functionality, but which may be individually soldered to one or more circuit boards in a same region or in different regions.

The control module 1316 (similar to or same as the control circuitry 902) can further include the image processing module 1304 and the digital control interfaces 1313 such as I²C. As will be appreciated, in some embodiments an image processing computation may be done by the control module 1316 through directly generating a modulated image. Alternatively, a standard image file can be processed or otherwise converted to provide modulation to match the image. Image data that mainly contains PWM duty cycle values can be processed for all pixels in image processing module 1304. Since amplitude is a fixed value or rarely changed value, amplitude related commands can be given separately through a simpler digital interface, such as I²C. The control module 1316 interprets digital data, which can be used by PWM generator 1310 to generate PWM signals for pixels, and by Digital-to-Analog Converter (DAC) 1312 to generate the control signals for obtaining the required current source amplitude.

In some embodiments, the pixel matrix 1320 in FIG. 13 can include m pixels including m common anode LEDs. In one example embodiment the pixel unit includes a single LED, LED1, and three transconductance devices (MOSFET switches) M1 through M3 and is supplied by the voltage supply V1 (sometimes called V_{LED}). M3 is an N-channel metal oxide semiconductor field effect transistor (MOSFET) whose gate is coupled to the amplitude control signal to generate the required current source amplitude. The P-channel MOSFET M1 is in parallel to LED1 and forms a totem pole pair with the N-channel MOSFET M2. The gates of the M1 and M2 transistor pair are tied together and coupled to the PWM signal. Therefore, when PWM is high, M1 will be turned off and M2 will be turned on. A current will flow through LED1, M2, and M3 with a value determined by the amplitude control signal coupled to M3 gate. When PWM is low, M1 will be turned on and M2 will be turned off. Consequently, the current source of M3 will be cut off and the LED will be fast discharged through M1.

To further illustrate the apparatus and related method disclosed herein, a non-limiting list of examples is provided below. Each of the following non-limiting examples can stand on its own or can be combined in any permutation or combination with any one or more of the other examples.

In Example 1 a segmented lighting apparatus includes a sapphire substrate, a patterned low refractive index material on the sapphire substrate, a photonic layer on the patterned low refractive index material, and a light-generating material on the photonic layer.

In Example 2, Example 1 further includes a nucleation layer between features of the patterned low refractive index material.

In Example 3, Example 2 further includes, wherein the light-generating material is situated on the nucleation layer and the photonic layer.

In Example 4, at least one of Examples 1-3 further includes, wherein the photonic layer includes a photonic material on the patterned low refractive index material and a low refractive index material on the photonic material.

In Example 5, Example 4 further includes, wherein the photonic material includes niobium pentoxide or titanium dioxide.

In Example 6, Example 5 further includes, wherein the low refractive index material and the patterned low refractive index materials include silicon dioxide.

In Example 7, Example 6 further includes, wherein the sapphire substrate includes a top surface through which the light is emitted and an opposing bottom surface through which light from the light generating material is received, and the photonic material conforms to surfaces of the patterned low refractive index material, the surfaces facing away from the top surface.

In Example 8, at least one of Examples 1-7 further includes, wherein the sapphire substrate includes a generally planar top surface through which the light is emitted and an opposing generally planar bottom surface through which light from the light generating material is received.

In Example 9, Example 8 further includes a reflector on a surface of the light generating material that faces away from the top surface of the sapphire substrate.

In Example 10, at least one of Examples 1-9 further includes, wherein the light generating material includes gallium nitride.

Example 11 includes a segmented lighting apparatus comprising a sapphire substrate, silicon dioxide features formed on the sapphire substrate, niobium pentoxide or titanium dioxide covering exposed portions of the silicon dioxide features, second silicon dioxide formed on the niobium pentoxide or titanium dioxide, and gallium nitride grown on the second silicon dioxide.

In Example 12, Example 11 further includes a nucleation layer separating silicon dioxide features.

In Example 13, Example 12 further includes, wherein the gallium nitride is situated in contact with the nucleation layer and the second silicon dioxide.

In Example 14, at least one of Examples 11-13 further includes, wherein the sapphire substrate includes a top surface through which the light is emitted and an opposing bottom surface through which light from the gallium nitride is received, and the niobium pentoxide or titanium dioxide conforms to surfaces of the silicon dioxide features, the surfaces facing away from the top surface.

In Example 15, at least one of Examples 11-14 further includes, wherein the sapphire substrate includes a generally planar top surface through which the light is emitted and an opposing generally planar bottom surface through which light from the gallium nitride is received.

In Example 16, Example 15 further includes a reflector on a surface of the gallium nitride that faces away from the top surface of the sapphire substrate.

Example 17 includes a method of making a segmented lighting apparatus, the method comprising forming silicon dioxide features on a sapphire substrate, situating niobium pentoxide or titanium dioxide on exposed portions of the silicon dioxide features, situating second silicon dioxide on the niobium pentoxide or titanium dioxide, and growing gallium nitride on the second silicon dioxide.

In Example 18, Example 17 further includes situating an aluminum nitride in contact with a bottom surface of the silicon substrate, the bottom surface situated to receive light from the gallium nitride and opposite a top surface of the sapphire substrate through which light is emitted, the aluminum nitride situated between the bottom surface and the gallium and between the sapphire substrate and the silicon dioxide features.

In Example 19, at least one of Examples 17-18 further includes situating a nucleation layer on the sapphire substrate so the nucleation layer horizontally separates features of the silicon dioxide features and is vertically between the sapphire substrate and the gallium nitride.

In Example 20, at least one of Examples 17-19 further includes, wherein, the sapphire substrate includes a top surface through which the light is emitted and an opposing bottom surface through which light from the gallium nitride is received, and the niobium pentoxide or titanium dioxide conforms to surfaces of the silicon dioxide features, the surfaces facing away from the top surface.

While example embodiments of the present disclosed subject matter have been shown and described herein, it will be obvious to those skilled in the art that such embodiments are provided by way of example only. Numerous variations, changes, and substitutions will now occur to those skilled in the art, upon reading and understanding the material provided herein, without departing from the disclosed subject matter. It should be understood that various alternatives to the embodiments of the disclosed subject matter described herein may be employed in practicing the various embodiments of the subject matter. It is intended that the following claims define the scope of the disclosed subject matter and that methods and structures within the scope of these claims and their equivalents be covered thereby.

1. A segmented lighting apparatus comprising:
a sapphire substrate;
a patterned low refractive index material on the sapphire substrate;
a photonic layer on the patterned low refractive index material; and
a light-generating material on the photonic layer.

2. The segmented lighting apparatus of claim 1, further comprising a nucleation layer between features of the patterned low refractive index material.

3. The segmented lighting apparatus of claim 2, wherein the light-generating material is situated on the nucleation layer and the photonic layer.

4. The segmented lighting apparatus of claim 1, wherein the photonic layer includes a photonic material on the patterned low refractive index material and a low refractive index material on the photonic material.

5. The segmented lighting apparatus of claim 4, wherein the photonic material includes niobium pentoxide or titanium dioxide.

6. The segmented lighting apparatus of claim 5, wherein the low refractive index material and the patterned low refractive index materials include silicon dioxide.

7. The segmented lighting apparatus of claim 6, wherein:
the sapphire substrate includes a top surface through which the light is emitted and an opposing bottom surface through which light from the light generating material is received, and
the photonic material conforms to surfaces of the patterned low refractive index material, the surfaces facing away from the top surface.

8. The segmented lighting apparatus of claim 1, wherein the sapphire substrate includes a generally planar top surface through which the light is emitted and an opposing generally planar bottom surface through which light from the light generating material is received.

9. The segmented light apparatus of claim 8, further comprising a reflector on a surface of the light generating material that faces away from the top surface of the sapphire substrate.

10. The segmented lighting apparatus of claim 1, wherein the light generating material includes gallium nitride.

11. A segmented lighting apparatus comprising:
a sapphire substrate;
silicon dioxide features formed on the sapphire substrate;
niobium pentoxide or titanium dioxide covering exposed portions of the silicon dioxide features;
second silicon dioxide formed on the niobium pentoxide or titanium dioxide; and
gallium nitride grown on the second silicon dioxide.

12. The segmented lighting apparatus of claim 11, further comprising a nucleation layer separating silicon dioxide features.

13. The segmented lighting apparatus of claim 12, wherein the gallium nitride is situated in contact with the nucleation layer and the second silicon dioxide.

14. The segmented lighting apparatus of claim 11, wherein:
the sapphire substrate includes a top surface through which the light is emitted and an opposing bottom surface through which light from the gallium nitride is received, and
the niobium pentoxide or titanium dioxide conforms to surfaces of the silicon dioxide features, the surfaces facing away from the top surface.

15. The segmented lighting apparatus of claim 11, wherein the sapphire substrate includes a generally planar top surface through which the light is emitted and an opposing generally planar bottom surface through which light from the gallium nitride is received.

16. The segmented light apparatus of claim 15, further comprising a reflector on a surface of the gallium nitride that faces away from the top surface of the sapphire substrate.

17. A method of making a segmented lighting apparatus, the method comprising:
forming silicon dioxide features on a sapphire substrate;
situating niobium pentoxide or titanium dioxide on exposed portions of the silicon dioxide features;
situating second silicon dioxide on the niobium pentoxide or titanium dioxide; and
growing gallium nitride on the second silicon dioxide.

18. The method of claim 17, further comprising:
situating an aluminum nitride in contact with a bottom surface of the silicon substrate, the bottom surface situated to receive light from the gallium nitride and opposite a top surface of the sapphire substrate through which light is emitted, the aluminum nitride situated between the bottom surface and the gallium and between the sapphire substrate and the silicon dioxide features.

19. The method of claim 17, further comprising:
situating a nucleation layer on the sapphire substrate so the nucleation layer horizontally separates features of the silicon dioxide features and is vertically between the sapphire substrate and the gallium nitride.

20. The method of claim 17, wherein,
the sapphire substrate includes a top surface through which the light is emitted and an opposing bottom surface through which light from the gallium nitride is received, and
the niobium pentoxide or titanium dioxide conforms to surfaces of the silicon dioxide features, the surfaces facing away from the top surface.
